(19) United States
(12) Patent Application Publication
(10) Pub. No.: US 2021/0122646 A1
(43) Pub. Date: Apr. 29, 2021

(54) WATER PURIFIER HAVING LIGHT-EMITTING ASSEMBLY

(71) Applicants: Xiaoping CHEN, Guangdong (CN); FOSHAN VIOMI ELECTRICAL TECHNOLOGY CO., LTD., Guangdong (CN)

(72) Inventor: Xiaoping CHEN, Guangdong (CN)

(21) Appl. No.: 16/616,989

(22) PCT Filed: May 24, 2018
(86) PCT No.: PCT/CN2018/088210

§ 371 Date: Nov. 26, 2019

(30) Foreign Application Priority Data
May 27, 2017 (CN) 201720608906.0

(51) Int. Cl. C02F 1/00; F21V 33/00

(52) U.S. Cl. CPC C02F 1/002; C02F 2201/002; F21V 33/0024

(57) ABSTRACT

Disclosed is a water purifier having a light-emitting assembly, comprising a light-emitting assembly (1), an outer housing (2), a middle frame (3) and a top cover (4). The light-emitting assembly (1) comprises a light ring support (11) and a light-emitting component mounted on the light ring support (11). The light-emitting assembly (1) is assembled on the middle frame (3). The middle frame (3), the light-emitting assembly (1) and the outer housing (2) are successively arranged from inside to outside. The top cover (4) is provided above the middle frame (3) and/or the outer housing (2), and the light ring support (11) is adjacent to or abuts the position of the top cover (4). The light-emitting assembly (1) of the water purifier emits light when lit, forming a uniform light-emission ring of emitted light at the top part of the light ring support (11), and can also be used for lighting.

### BACKGROUND OF THE INVENTION

The present invention relates to a water purifier, and in particular to a water purifier with a light-emitting assembly.

At present, a plurality of water purifiers on the market has been equipped with a light-emitting assembly to achieve the purpose of lighting and beautifying the water purifier. However, a conventional water purifier equipped with the light-emitting assembly on the market cannot form a light-emitting ring.

In addition, the water purifier and/or the light-emitting assembly in the prior art have technical problems of uneven lighting and insufficient brightness.

### BRIEF SUMMARY OF THE INVENTION

In order to solve the above problems, an object of the present invention is to provide a water purifier with a light-emitting assembly, which has a simple and reasonable structure, and si easy to install and forms a light-emitting ring.

The detailed technical solution adopted by the present invention is:

A water purifier with a light-emitting assembly comprises a light-emitting assembly, a casing, a middle frame and a top cover, wherein the light-emitting assembly comprises a lamp ring bracket, and a light-emitting assembly mounted on the lamp ring bracket the light-emitting assembly is mounted on the middle frame, the middle frame. The light-emitting assembly and the casing are sequentially arranged from the inside to the outside. The top cover is arranged on the upper portion of the middle frame and/or the casing, and the lamp ring bracket is adjacent to or opposite to the position of the top cover.

When the light-emitting assembly is illuminated to emit light, the light emitted by the light-emitting assembly is blocked by the casing and the middle frame, and is concentrated toward the top of the lamp ring bracket, thereby forming a light-emitting ring with uniform lighting on the top of the lamp ring bracket, and also be able to play a role of lighting.

Further, the lamp ring bracket is exposed upwardly between the middle frame and the casing, and the lamp ring bracket is made of a transparent material, which is more favorable for improving the brightness and the uniform effect of the light.

Further, the middle frame and the casing are made of an opaque material to prevent light from being scattered away via the middle frame and the casing, thereby affecting the brightness and the uniform effect of the light.

Further, the circumference of the top cover is made of a transparent or translucent light-transmission material, and the top cover can serve as a sealing function, which is favorable for forming a light-emitting ring with better effect on the top cover.

Further, a top cover is further comprised, and a top end of the middle frame is lower than that of the casing, so that the middle frame and the casing are assembled to form a groove. The top cover is placed in the groove formed by the middle frame and the casing.

When the light-emitting assembly is lit, the light on the top of the lamp ring bracket can be irradiated on the top cover, so that the top cover also forms a visible light ring, the light is even and beautiful, and can also function as lighting.

Preferably, the lamp ring bracket is entirely annular and provided with a recess. The light-emitting assembly is a PCB board, the PCB board is provided with an external wire electrically connected to the PCB board, and at least two light-emitting bodies. The PCB board is provided inside the groove and fixed.

Preferably, the light-emitting bodies are evenly distributed along the PCB board.

Preferably, the light-emitting body is an LED lamp.

Preferably, the recess is filled with a light guiding colloid to fix the PCB board in the recess.

The light emitted by the light-emitting body can be uniformly radiated along the light guiding colloid by the light guiding colloid, so that the light-emitting assembly uniformly emits light.

Preferably, the PCB board is a bendable PCB board.

When the PCB board is placed in the recess, the diameter of the ring formed by bending the bendable PCB board can be adjusted to facilitate the placement of the PCB board into the recess, thereby facilitating the assembly of the light-emitting assembly.

Compared with the prior art, The present invention has the following beneficial effects:

(1) When the light-emitting assembly is illuminated to emit light, the light emitted by the light-emitting assembly is blocked by the casing and the middle frame, and is concentrated toward the top of the lamp ring bracket, thereby forming a light-emitting ring with uniform lighting on the top of the lamp ring bracket, and be able to play a role of lighting;

(2) the top cover can also form a circle of visible light, the light is even and beautiful, and can also play a role of lighting;

(3) The light emitted by the light-emitting body can be uniformly irradiated along the light guiding colloid via the light guiding colloid, so that the light-emitting assembly uniformly emits light;

(4) The assembly of the light-emitting assembly is convenient.

### BRIEF DESCRIPTION OF THE DRAWINGS

FIG. 1 is a perspective exploded view of a water purifier with a light-emitting assembly according to the present invention.

FIG. 2 is a half sectional view of a water purifier with a light-emitting assembly according to the present invention.

FIG. 3 is a perspective exploded view of a light-emitting assembly.

FIG. 4 is a half cross-sectional view of a light-emitting assembly.

FIG. 5 is an enlarged schematic view of position A.

Light-emitting assembly 1; lamp ring bracket 11; recess 111; PCB board 12; light-emitting body 13; external wire 14; casing 2; middle frame 3;

### DETAILED DESCRIPTION OF THE INVENTION

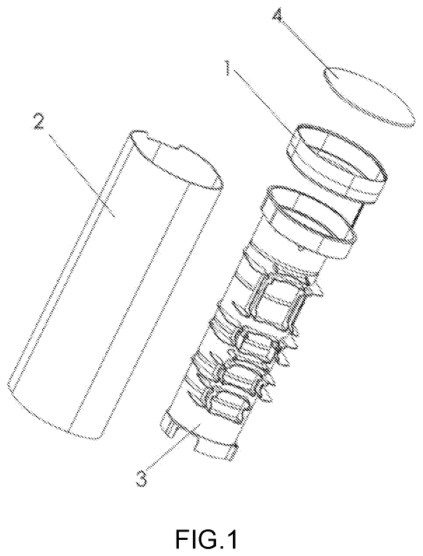

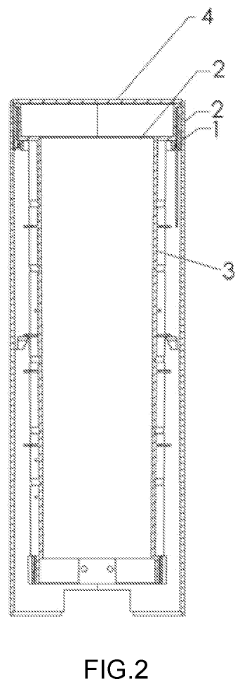

Please refer to FIG. 1 and FIG. 2, the present invention relates to a water purifier with a light-emitting assembly, comprising the light-emitting assembly 1, a casing 2, and a middle frame 3. Here, the middle frame 3 is a frame in the prior art in which a component for water purification is installed.

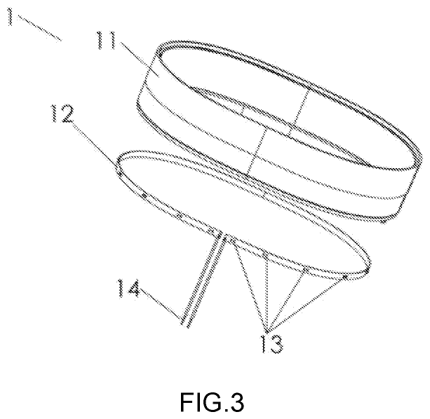

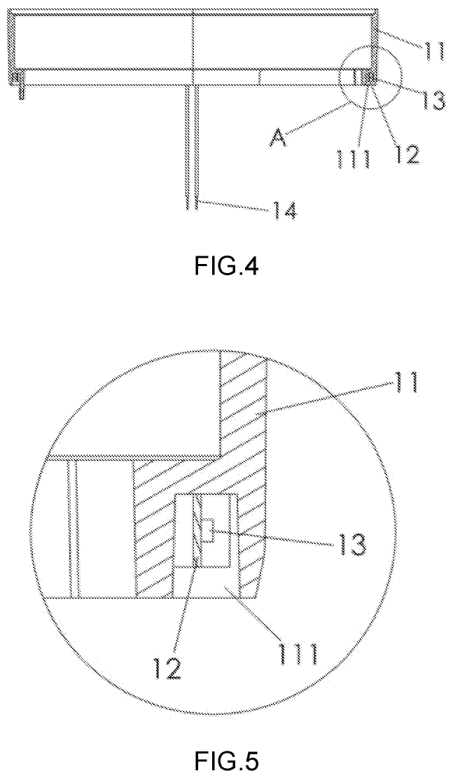

Referring to FIGS. 3-5, the light-emitting assembly 1 comprises a lamp ring bracket 11 and a light-emitting assembly.

The lamp ring bracket 11 is entirely annular and is provided with a recess 111.

The light-emitting component is a PCB board 12, and the PCB board 12 is provided with an external wire 14 electrically connected to the PCB board 12, and at least two light-emitting bodies 13, and the light-emitting bodies 13 are evenly distributed along the PCB board 12. Preferably, the light-emitting body 13 is an LED lamp.

The PCB board 12 is placed in the recess 111 and fixed so that the light-emitting bodies 13 are evenly distributed in the recess 111. Preferably, a light guide colloid is filled in the recess 111 to fix the PCB board 12 inside the recess 111. The light emitted by the light-emitting body 13 can be uniformly radiated along the light guide colloid via the light guide colloid, so that the light-emitting assembly 1 uniformly emits light.

In use, the external lead 14 is electrically connected to a power source to cause the respective light-emitting bodies 13 to emit light, and the lamp ring bracket 11 uniformly emits light under the lighting of each of the light-emitting bodies 13, and has a relatively bright brightness.

Preferably, the PCB board 12 is a bendable PCB board. When the PCB board 12 is placed in the recess 111, the diameter of the ring formed by bending the bendable PCB board 12 can be adjusted to facilitate the placement of the PCB board 12 into the recess 111, thereby facilitating the assembly of the light-emitting assembly 1.

The light-emitting assembly 1 is assembled on the middle frame 3. The middle frame 3, the light-emitting assembly 1 and the casing 2 are sequentially arranged from the inside to the outside. The lamp ring bracket 11 is exposed upwardly between the middle frame 3 and the casing 2, and is made of a transparent material. The middle frame 3 and the casing 2 are made of an opaque material. When the light-emitting assembly 1 is illuminated to emit light, the light emitted by the light-emitting assembly 1 is blocked by the casing 2 and the middle frame 3, and is concentrated toward the top of the light ring holder 11, thereby forming a light-emitting ring with uniform lighting on the top of the light ring holder 11 and be able to play a role in lighting.

The water purifier with the light-emitting assembly further comprises a top cover 4, the top end of the middle frame 3 is lower than that of the casing 2, so that the middle frame 3 and the casing 2 are assembled to form a groove. The top cover 4 is placed in the groove formed by the assembly of the middle frame 3 and the casing 2. The top cover 4 can function as a seal.

Further, the circumference of the top cover 4 (i.e., a region formed by a portion exposed upward between the middle frame 3 and the casing 2 projected on the top cover 4) is made of a transparent or translucent transparent material. When the light-emitting assembly 1 is illuminated, the light on the top of the lamp ring bracket 11 can be irradiated on the top cover 4, so that the top cover 4 also forms a circle of visual light ring, the light is even and beautiful, and can also function as lighting.

It should be understood that the orientation or positional relationship indicated by the terms “center”, “longitudinal”, “transverse”, “front”, “back”, “left”, “right”, “vertical”, “horizontal”, “top”, “inner” and “outside” and the like are based on the orientation or positional relationship shown in the accompanying drawings, and are merely for convenience and simplification of description of the present invention, rather than indicating or implying the indicated device or an element shall have a particular orientation and be configured and operated for a particular orientation, and thus is not to be construed as limiting the scope of the invention.

The above specific embodiments are merely preferred embodiments the present invention, and are not intended to limit the present invention. Any modification, equivalent substitution, improvement, etc. made within the spirit and principles of the present invention should be comprised within the scope of the present invention.

1: A water purifier with a fight-emitting assembly, comprising the light-emitting assembly (1), a casing (2), a middle frame (3) and a top cover (4), wherein the light-emitting assembly (1) comprises a lamp ring bracket (11) and a light-emitting component mounted on the lamp ring bracket (11), the light-emitting assembly (1) is assembled on the middle frame (3), the middle frame (3), the light-emitting assembly (1) and the casing (2) are sequentially arranged from the inside to the outside, the top cover (4) is arranged at an upper portion of the middle frame (3) and/or the casing (2), and the lamp ring bracket (11) is adjacent to or opposite to the position of the top cover (4).

2: The water purifier with the light-emitting assembly according to claim 1, wherein the lamp ring bracket (11) is exposed upwardly between the middle frame (3) and the casing (2), and the lamp ring bracket (11) is made of a transparent material.

3: The water purifier with the light-emitting assembly according to claim 1, wherein the middle frame (3) and the casing (2) are both made of an opaque material.

4: The water purifier with the light-emitting assembly according to claim 1, wherein the circumference of the top cover (4) is made of a transparent or translucent light transmissive material.

5: The water purifier with the light-emitting assembly according to claim 1, further comprising the top cover (4), the top end of the middle frame (3) being lower than that of the casing (2) such that the middle frame (3) is assembled with the casing (2) to form a groove, and the top cover (4) being placed in the groove formed by the assembly of the middle frame (3) and the casing (2).

6: The water purifier with the light-emitting assembly according to claim 5, wherein the lamp ring bracket (11) is entirely annular and is provided with a recess (111), and the light-emitting component is a PCB board (12), the PCB board (12) is provided with an external wire (14) electrically connected to the PCB board (12), and at least two light-emitting bodies (13), and the PCB board (12) is placed in the recess (111) and fixed.

7: The water purifier with the light-emitting assembly according to claim 6, wherein each of the light-emitting bodies (13) is evenly distributed along the PCB board (12).

8: The water purifier with the light-emitting assembly according to claim 6, wherein that the light-emitting body (13) is an LED lamp.

9: The water purifier with the light-emitting assembly according to claim 7, wherein the recess (111) is filled with a light guiding colloid to fix the PCB board (12) inside the recess (111).

10: The water purifier with the light-emitting assembly according to claim 7, wherein the PCB board (12) is a flexible PCB board.
